(19) United States
(12) Patent Application Publication
(10) Pub. No.: US 2003/0217462 A1
(43) Pub. Date: Nov. 27, 2003

(54) Method for improving electromigration performance of metallization features through multiple depositions of binary alloys

(76) Inventors: Fei Wang, San Jose, CA (US); Brian J. MacDonald, San Francisco, CA (US); Amit P. Marathe, Milpitas, CA (US); John E. Sanchez, Palo Alto, CA (US); Pin-Chin C. Wang, Menlo Park, CA (US); Joffre F. Bernard, Redwood City, CA (US)

Correspondence Address: David A. Blumenthal, FOLEY & LARDNER, Suite 3500, 2029 Century Park East, Los Angeles, CA, 90067-3021, US

(21) Appl. No.: 10/021,994

(22) Filed: Dec. 13, 2001

(51) Int. Cl. H05K 1/00; H05K 3/00

(52) U.S. Cl. 29/846; 29/830; 29/840; 29/829; 174/254

(57) ABSTRACT

The reliability and electromigration performance of planarized metallization patterns in an electrical device, for example copper, inlaid in the surface of a layer of dielectric material overlying a semiconductor substrate, are enhanced by a method for more reliably and uniformly diffusing into a conductive fill alloying elements which reduce or substantially prevent electromigration. The method comprises depositing around a conductive fill metal alloy films and alloying layers comprising one or more alloying elements having physical and/or chemical attributes which are effective for minimizing or substantially preventing electromigration along grain boundaries and/or along the interface between the surfaces of the conductive fill and other surfaces. The metal alloy films and alloying layers are advantageously deposited where their particular physical and/or chemical attributes may be most beneficial for improving electromigration performance. The alloying elements may then be diffused into the conductive fill to effect alloying therewith.

### BACKGROUND OF THE INVENTION

1. Field of the Invention

The present invention relates to electrical devices, for example semiconductor integrated circuit devices, having inlaid (“damascene”-type) metallization patterns, for example interconnection lines, etc., and to a method for minimizing, or substantially preventing, deleterious electromigration of the metallic feature(s) of the metallization pattern. More specifically, the present invention relates to semiconductor devices comprising copper (Cu) interconnection patterns and is applicable to manufacture of high speed integrated circuits having sub-micron dimensioned design features and high electrical conductivity interconnect structures.

2. Description of Related Art

The present invention relates to a method for forming metal films as part of metallization processing of particular utility in the manufacture of electrical and electronic devices, for example circuit boards and semiconductor integrated circuits, and is especially adapted for use in processing employing “inlaid” or damascene-type technology.

The escalating requirements for high density and performance associated with ultra-large scale integration (ULSI) semiconductor device wiring are difficult to satisfy in terms of providing sub-micron-sized (e.g., 0.18 μm and under), low resistance-capacitance (RC) time constant metallization patterns, particularly where the sub-micron-sized metallization features, such as vias, contact areas, lines, etc. require grooves, trenches, and other shaped openings or recesses having very high aspect (i.e., depth-to-width) ratios due to microminiaturization.

Semiconductor devices of the type contemplated herein typically comprise a semiconductor substrate, usually of doped monocrystalline silicon (Si) or, in some instances, gallium arsenide (GaAs), and a plurality of sequentially formed interlayer dielectrics and electrically conductive patterns formed therein and/or therebetween. An integrated circuit is formed therefrom containing a plurality of patterns of conductive lines separated by interwiring spacings, and a plurality of interconnect lines, such as bus lines, bit lines, word lines, and logic interconnect lines. Typically, the conductive patterns of vertically spaced-apart metallization layers or strata are electrically interconnected by a vertically oriented conductive plug filling a via hole formed in the inter-layer dielectric layer separating the layers or strata, while another conductive plug filling a contact area hole establishes electrical contact with an active device region, such as a source/drain region of a transistor, formed in or on the semiconductor substrate. Conductive lines formed in groove- or trench-like openings in overlying inter-layer dielectrics extend substantially parallel to the semiconductor substrate. Semiconductor devices of such type fabricated according to current technology may comprise five or more layers or strata of such metallization in order to satisfy device geometry and microminiaturization requirements.

Electrically conductive films or layers of the type contemplated for use in, for example, “back-end” semiconductor manufacturing technology for fabricating devices having multi-level metallization patterns such as described supra, typically comprise a metal such as titanium (Ti), tantalum (Ta), tungsten (W), aluminum (Al), chromium (Cr), nickel (Ni), cobalt (Co), silver (Ag), gold (Au), copper (Cu) or their alloys. In use, each of the enumerated metals presents advantages as well as problems. For example, Al is relatively inexpensive, exhibits low resistivity, and is relatively easy to etch. However, in addition to being difficult to deposit by lower cost, lower temperature, more rapid “wet” type technology such as electrodeposition, step coverage with Al is poor when the metallization features are scaled down to sub-micron size, resulting in decreased reliability of interconnections, high current densities at certain locations, and increased electromigration. In addition, certain low dielectric constant materials, for example polyimides, when employed as dielectric inter-layers, create moisture/bias reliability problems when in contact with Al.

Cu and Cu-based alloys are particularly attractive for use in large scale integration (LSI), very large-scale integration (VLSI), and ultra-large scale (ULSI) semiconductor devices requiring multi-level metallization systems for “back-end” processing of the semiconductor wafers on which the devices are based. Cu- and Cu alloy-based metallization systems have very low resistivities, i.e., significantly lower than that of W and even lower than those of previously preferred systems utilizing Al and its alloys, as well as a higher (but not complete) resistance to electromigration. Moreover, Cu and its alloys enjoy a considerable cost advantage over a number of the above-enumerated metals, notably Ag and Au. Also, in contrast to Al and the refractory-type metals (e.g., Ti, Ta, and W), Cu and its alloys can be readily deposited at low temperatures in good quality, bright layer form by well-known “wet” plating such as electroless and electroplating techniques, at deposition rates fully compatible with the requirements of device manufacturing throughput.

As indicated above, a commonly employed method for forming inlaid metallization patterns as are required for “back-end” metallization processing of semiconductor wafers employs damascene-type technology. Generally, in such processing methodology, a recess (i.e., an opening for forming, for example, a via hole in a dielectric layer for electrically connecting vertically separated metallization layers, or a groove or trench for a metallization line) is created in the dielectric layer by conventional photolithographic and etching techniques, and filled with a selected metal. Any excess metal overfilling the recess and/or extending over the surface of the dielectric layer is then removed by, for example, chemical-mechanical polishing (CMP), wherein a moving pad is biased against the surface to be polished/planarized, with the interposition of a slurry containing abrasive particles (and other ingredients) therebetween.

A variant of the above-described technique, termed “dual damascene” processing, involves the formation of an opening comprising a lower contact or via hole section in communication with an upper groove or trench section, which opening is filled with a conductive material, typically a metal, to simultaneously form a conductive via plug in electrical contact with a conductive line.

Referring now to FIGS. 1A-1C, schematically shown therein in simplified cross-sectional view, is a conventional damascene-type processing sequence employing relatively low cost, high manufacturing throughput plating and CMP techniques for forming recessed “back-end” metallization patterns (illustratively of Cu-based metallurgy but not limited thereto) in a semiconductor device formed in or on a semiconductor substrate 1. As shown in FIG. 1A, the desired arrangement of conductors is defined as a pattern of recesses 2 such as via holes, grooves, trenches, etc. formed (as by conventional photolithographic and etching techniques) in the surface 4 of a dielectric layer 3 (e.g., a silicon oxide and/or nitride or an organic polymeric material) deposited or otherwise formed over the semiconductor substrate 1. Then, as shown in FIG. 1B, a layer of conductive metal 5, for example, Cu or Cu-based alloy, is deposited by conventional plating techniques, for example electroless or electroplating techniques, to fill the recesses 2. In order to ensure complete filling of the recesses, the conductive metal 5 is deposited as a blanket (or “overburden”) layer of excess thickness so as to overfill the recesses 2 and cover the upper surface 4 of the dielectric layer 3. Next, as shown in FIG. 1C, the entire excess thickness t of the overburden layer of conductive metal 5 over the surface 4 of the dielectric layer 3 is removed by a CMP process utilizing, for example, an alumina (A1203)-based slurry, leaving metal portions 5 in the recesses 2 with their exposed upper surfaces 6 substantially co-planar with the surface 4 of the dielectric layer 3.

The above-described conventional damascene-type process forms inlaid conductors (metal portions 5) in the dielectric layer 3 while avoiding problems associated with other types of metallization patterning processing, for example blanket metal layer deposition, followed by photolithographic masking/etching and dielectric gap filling. In addition, such single or dual damascene-type processing can be performed with a variety of other types of substrates, for example printed circuit boards, with and/or without intervening dielectric layers, and with a plurality of metallization levels, i.e., five or more levels.

A problem associated with Cu-based “back-end” metallization is the possibility of Cu diffusion into adjacent structures, for example an underlying semiconductor substrate (typically Si) or a dielectric layer, resulting in degradation of semiconductive or insulative properties, as well as poor adhesion of the deposited Cu or Cu alloy layer to various materials employed as dielectric inter-layers, etc. As a consequence of these phenomena associated with Cu-based metallurgy, it is generally necessary to provide an adhesion and/or diffusion barrier layer (not shown in FIGS. 1A through 1C) intermediate the semiconductor substrate and the overlying Cu-based metallization layer. Suitable materials for such adhesion/barrier layers include, for example, Ti, W, Cr, Ta, and tantalum nitride (TaN).

Another problem associated with the use of Cu or Cu-based metallurgy for “back-end” metallization processing of semiconductor devices is that Cu interconnects tend to form a weaker interface than aluminum interconnects with the barrier materials and with passivation layer materials. As a result, the interface of a copper interconnect line with the surrounding barrier and passivation materials can act as a fast diffusion path for electromigration.

Electromigration occurs in extended runs or lengths of metal conductor lines carrying significant currents. According to a conventional theory for explaining the mechanism of electromigration, the current flow within the conductor line can be sufficient to result in movement of Cu ions and/or atoms along the line via momentum transfer engendered by collision of the Cu ions and/or atoms with energetic, flowing electrons. The current flow also creates a thermal gradient along the conductor length which increases the mobility of the metal ions and/or atoms. As a consequence of the momentum transfer and the thermally enhanced mobility, metal (Cu) ions and/or atoms diffuse in the direction of the gradient, and metal (Cu) loss at the source end of the conductor eventually results in thinning of the conductor line. The electromigration effect can continue until the conductor line becomes so thin that it separates from the current input or forms an open circuit, resulting in circuit (i.e., semiconductor chip) failure. As this usually occurs over an extended period of operation, the failure is often seen by the end-user.

An additional problem leading to increased electromigration arises from the fact that damascene structures typically have small metal grains compared to etched metal lines. The small metal grains result from deposition of the metal into a constrained via and/or trench, as opposed to deposition as a blanket film in the case of etched metal features. Interconnects with large grains typically show better electromigration reliability because they provide fewer grain boundary diffusion paths during electromigration. Ions and/or atoms diffuse faster along grain boundaries than through the bulk of the grains.

As is known, Cu electromigration can be reduced by adding to the Cu certain alloying elements, for example, tin (Sn), boron (B), magnesium (Mg), carbon (C), palladium (Pd), cobalt (Co), nickel (Ni), and cadmium (Cd). A typical process for adding the alloying elements is the deposition of an alloy containing seed layer on the bottom of the recess followed by diffusion of the alloying element into subsequently formed bulk Cu filling the recess. However, this process fails to provide adequate alloy composition uniformity, especially near the top surface of the bulk Cu. Thus, electromigration may not be reliably and uniformly reduced throughout the bulk Cu.

Furthermore, different alloying elements may be more or less effective at reducing electromigration along metal grain boundaries, while others may be more or less effective at reducing electromigration along an interface between the damascene structures and other surfaces such as the surface of a barrier or passivation layer.

Thus, there exists a need for a metallization process methodology which more uniformly and reliably distributes alloying elements throughout the bulk Cu to overcome the above-mentioned problems of deleterious electromigration along small metal grain boundaries of the damascene structures and along a weak interface between the damascene structures and the barrier and passivation materials.

Furthermore, there exists a need for a metallization process methodology which enables formation of damascene structures, for example interconnect and routing lines (particularly of Cu or Cu-based alloys) having high reliability, high product yield, more reliable and uniform electromigration resistance, and high electromigration performance.

Moreover, there exists a need for improved metallization processing technology which is fully compatible with conventional process flow, methodology, and throughput requirements in the manufacture of integrated circuit semiconductor devices and other devices requiring inlaid metallization patterns.

### SUMMARY OF THE DISCLOSURE

Embodiments of the invention pertain to methods of manufacturing electrical or electronic devices having highly reliable, electromigration-resistant metallization patterns.

Additional embodiments of the invention pertain to methods of manufacturing semiconductor integrated circuit devices having highly reliable, electromigration-resistant Cu-based metallization patterns.

Yet other embodiments of the invention pertain to methods of manufacturing inlaid, damascene-type Cu-based metallization patterns having improved reliability, high conductivity, and improved electromigration resistance.

Preferred embodiments of the invention address the foregoing shortcomings of the conventional technology by providing methods of reducing electromigration in a conductive fill by diffusing an amount of two or more alloying elements into the conductive fill. In one embodiment, a metal alloy film comprising a first group of one or more alloying elements may be formed on surfaces of a recess before the conductive fill is deposited into the recess. Because the metal alloy film is deposited before the conductive fill, the alloying elements in the metal alloy film may be deposited around the subsequently deposited conductive fill in a more conformal manner.

The first group of one or more alloying elements may have attributes that are beneficial in protecting against diffusion of the subsequently deposited conductive layer into the surrounding dielectric layer. Thus, one advantage of forming the metal alloy film in the recess before depositing the conductive fill is that an additional adhesion/barrier layer of, for example, TaN, may not be required on the surfaces of the recess prior to the forming of the metal alloy film, or may be formed at a reduced thickness. An additional advantage is that the first group of one or more alloying elements may also have attributes that are beneficial in reducing electromigration along grain boundaries and/or along the interface between the surfaces of the metallization features and other surfaces.

The conductive fill may then be deposited into the recess. Subsequent to the deposition of the conductive fill into the recess, a planarization step may be performed. After planarization, an alloying layer comprising a second group of one or more alloying elements may be formed over and diffused into the conductive fill. The second group of one or more alloying elements may have attributes that are beneficial in providing better adhesion between the conductive fill and a subsequently deposited passivation layer. The second group of one or more alloying elements may also have attributes that are beneficial in reducing electromigration along grain boundaries and/or along the interface between the surfaces of the metallization features and other surfaces. One advantage of introducing the second group of one or more alloying elements after planarization is that the resulting evenness of the surface of the conductive fill allows a more uniform density of the alloying elements within wide and narrow metal lines. Another advantage is that the alloying element may be diffused to a depth close to the surface of the conductive fill. Thus, the adhesion enhancing attributes of the alloying elements may be more advantageously employed.

In accordance with preferred embodiments, a substrate is provided including a dielectric layer overlying at least a portion of the substrate. The dielectric layer may have an upper, exposed surface having recesses formed therein. The recesses may be inlaid with composite conductive layers comprising one or more metal alloy films formed on the surfaces of the recesses and conductive fill (for example, Cu) electroplated or electroless plated over the metal alloy films. A planarization step results in the conductive fill having upper, exposed surfaces substantially co-planar with the upper, exposed surface of the dielectric layer.

The one or more metal alloy films may comprise a first group of one or more alloying elements which may have different physical and/or chemical attributes which may be more effective at, for example, providing a barrier to Cu diffusion into a surrounding dielectric and/or minimizing or substantially preventing electromigration along grain boundaries.

After planarization, one or more alloying layers may be deposited on the planarized upper, exposed surfaces of the conductive fill and the dielectric layer. The one or more alloying layers may comprise a second group of one or more alloying elements which may have different physical and/or chemical attributes than the first group. The second group may be more effective at, for example, providing better adhesion between the conductive fill and a subsequently formed passivation layer or other layer in contact with the conductive fill and/or minimizing or substantially preventing electromigration along the interface between the surfaces of the metallization features and other surfaces.

An amount of the one or more alloying elements from the first and second groups surrounding the conductive fill may be more uniformly and reliably diffused into the conductive fill such that electromigration of the conductive fill is reduced or substantially prevented. Any remaining alloyed and/or unalloyed portions of the one or more alloying layers which extend above the surface of the dielectric layer may then be removed such that the upper, exposed surface of the conductive fill is substantially co-planar with the upper, exposed surface of the dielectric layer.

In a preferred embodiment of the invention, the electrical device may comprise a semiconductor integrated circuit device and the substrate may comprise a semiconductor material such as monocrystalline silicon (Si) or gallium arsenide (GaAs) having a major surface, with the dielectric layer being formed over at least a portion of the major surface, and the recesses inlaid with composite conductive layers may comprise a plurality of unalloyed Cu features for providing vias, interlevel metallization, and/or interconnection lines of at least one active device region or component formed on or within the semiconductor wafer. The first group of one or more alloying elements may include, but is not limited to, magnesium (Mg) and calcium (Ca). The second group of one or more alloying elements may include, but is not limited to, zirconium (Zr), tin (Sn), and palladium (Pd).

These and other objects, features, and advantages of embodiments of the invention will be apparent to those skilled in the art from the following detailed description of embodiments of the invention, when read with the drawings and appended claims.

### BRIEF DESCRIPTION OF THE DRAWINGS

Referring now to the drawings in which like reference numbers represent corresponding parts throughout:

FIGS. 1A, 1B and 1C illustrate, in cross-sectional schematic form, a process for forming a pattern of damascene-type, inlaid Cu metallization features according to conventional practices for manufacture of semiconductor integrated circuit devices; and

FIGS. 2A, 2B, 2C, 2D, 2E, 2F, 2G, 2H, and 21 illustrate, in cross-sectional schematic form, a process for depositing and more uniformly and reliably diffusing one or more alloying elements into the metallization features, according to embodiments of the present invention.

FIG. 3 shows a process flow diagram illustrating an embodiment of the present invention.

### DETAILED DESCRIPTION OF PREFERRED EMBODIMENTS

In the following description of preferred embodiments, reference is made to the accompanying drawings which form a part hereof, and in which are shown by way of illustration specific embodiments in which the invention may be practiced. It is to be understood that other embodiments may be utilized and structural changes may be made without departing from the scope of the invention.

Embodiments of the present invention address problems arising from manufacturing electrical devices comprising inlaid metallization patterns, for example semiconductor integrated circuit devices, wherein, as part of the fabrication methodology, a plurality of recesses formed in the surface of a dielectric layer overlying a substrate comprising at least one active device region or component are filled with a metal, illustratively Cu, which is subject to electromigration when the device is in use. Embodiments of the present invention particularly enable the formation of inlaid metallization patterns, for example Cu metallization patterns, in which the tendency for electromigration of the principal metallic element or component is reduced or substantially prevented.

The present invention enables the formation of inlaid metallization features comprising multiple alloying elements substantially uniform in their distribution within the metallization features, the multiple alloying elements providing different physical and/or chemical attributes. Some of the alloying elements may be more effective at providing a barrier for preventing diffusion of the conductive fill into a surrounding dielectric and/or minimizing or substantially preventing electromigration along grain boundaries of the metal used for the metallization features. Others of the alloying elements may be more effective at providing better adhesion between the conductive fill and a passivation layer or other layer in contact with the conductive fill and/or minimizing or substantially preventing electromigration of the metal used for the metallization features at the interface between the surfaces of the metallization features and other surfaces. These other surfaces may include, but are not limited to, the surface of a passivation layer or barrier layer. Therefore, the present invention may improve electromigration performance of metallization features manufactured according to embodiments of the present invention.

Briefly stated, according to preferred embodiments of the present invention, a suitable substrate is provided, for example, a semiconductor wafer comprising at least one active device region or component, with at least one recess formed by conventional damascene-type methodology in a dielectric layer overlying at least a portion of the substrate. The recess is inlaid with a composite conductive layer which may comprise at least one metal alloy film formed on surfaces of the recess (for example, on the bottom and sidewalls of the recess) and a conductive fill plated over the metal alloy film. The conductive fill may comprise electroplated or electroless plated metal and may, after a planarization step, have an upper, exposed surface substantially co-planar with the upper, exposed surface of the dielectric layer.

According to preferred embodiments of the present invention, at least one alloying layer comprising at least one alloying element may be deposited on the exposed, upper surfaces of the conductive fill and dielectric layer, as by a suitable physical vapor deposition (PVD) technique, including, but not limited to, sputtering, ion plating, and vacuum evaporation. The thus-produced structure is subjected to thermal processing, for example annealing in an inert atmosphere, to substantially uniformly diffuse into, and alloy with, at least a portion of the conductive fill (e.g., Cu) filling the recess.

Any excess alloyed and/or unalloyed, elevated portions of the at least one alloying layer comprising at least one alloying element remaining after diffusion/alloying may then be removed, as by CMP, thereby making the exposed, upper surface of the inlaid conductive fill substantially co-planar with the exposed, upper surface of the dielectric layer.

In preferred embodiments of the present invention, multiple alloy films as well as multiple layers, comprising multiple alloying elements, may be advantageously employed in the present invention's process, the multiple alloying elements having different physical and/or chemical attributes which may be more effective at, for example, minimizing or substantially preventing electromigration along grain boundaries and/or along the interface between the surfaces of the metallization features and other surfaces.

In addition, preferred embodiments of the present invention enable one or more alloying elements to be distributed below the top surface of the conductive fill such that a more reliable and uniform distribution of multiple alloying elements may be achieved. Therefore, the present invention may improve electromigration performance of metallization features manufactured according to preferred embodiments of the present invention.

As will be apparent to one of ordinary skill in the art, embodiments of the present invention are readily adapted for use in the manufacture of a variety of electrical and electronic devices utilizing inlaid metallization patterns, for example printed circuit boards and integrated circuit devices. It should also be recognized that the processes and structures described below do not necessarily form a complete process flow for manufacturing such devices. However, the present invention can be used in conjunction with conventional technology currently employed in the art, for example integrated circuit fabrication methodology, and, consequently, only so much of the commonly practiced processes are included here as are necessary for an understanding of the present invention. As employed throughout the disclosure and claims, the term “substrate” and/or “semiconductor wafer substrate” includes, for example, a semiconductor substrate per se or an epitaxial layer formed on a suitable semiconductor substrate. Finally, the drawing figures representing cross-sections of portions of a semiconductor device during fabrication processing are not drawn to scale, but instead are drawn as to best illustrate the features of the present invention.

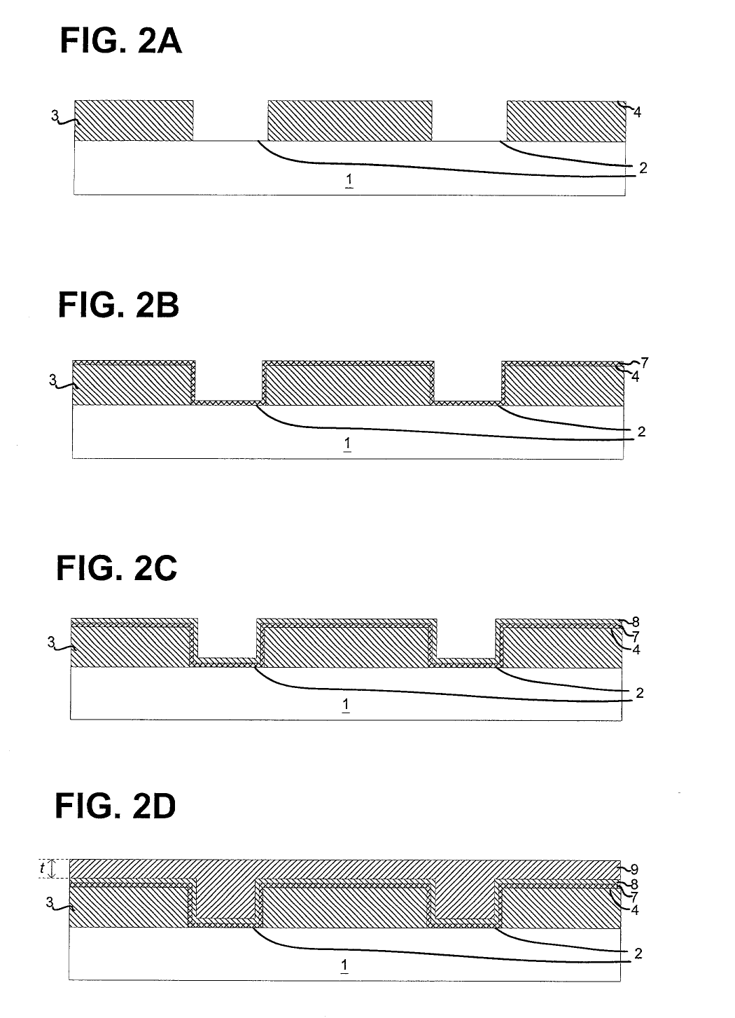

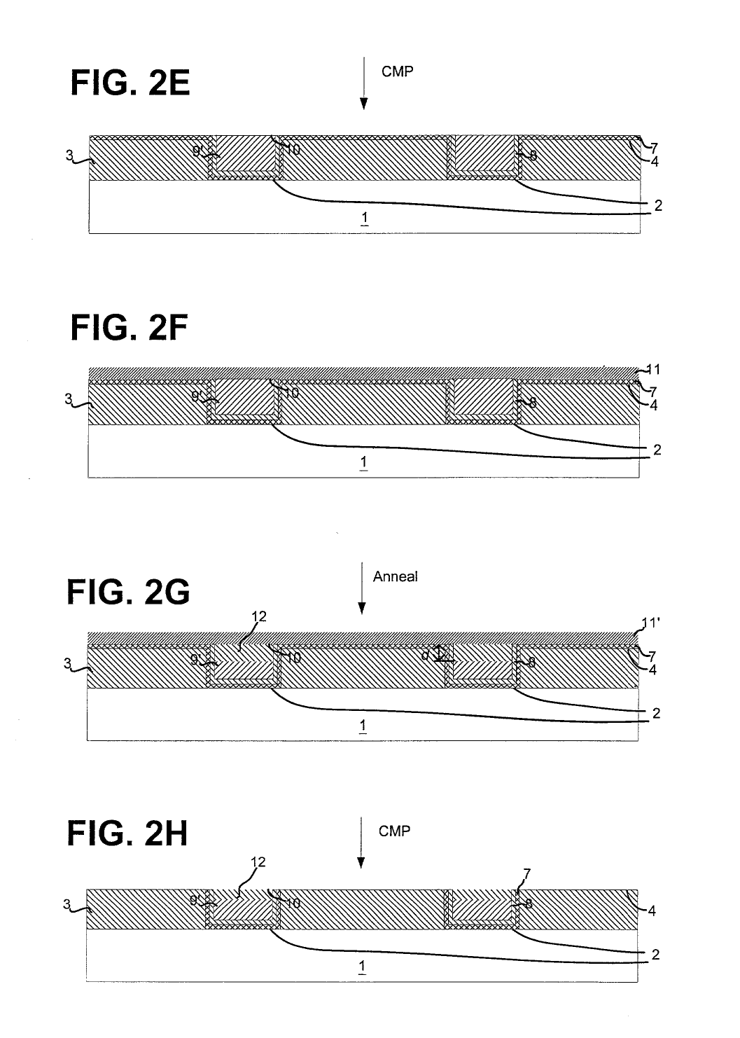

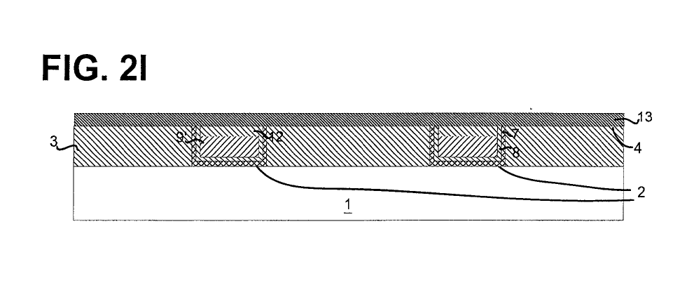

An embodiment of the present invention will now be described with reference to FIGS. 2A through 2I, which show, in cross-sectional, schematic fashion, an illustrative, but not limiting, embodiment of the present invention.

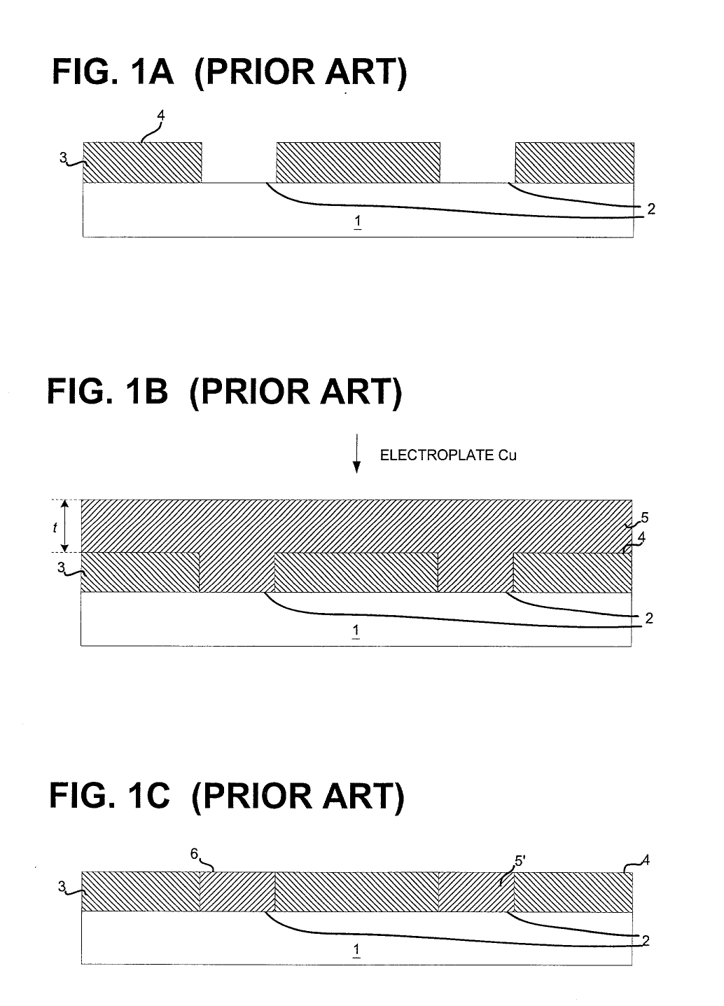

As shown in FIG. 2A, according to embodiments of the present invention, a semiconductor substrate-based workpiece similar to that shown in FIG. 1A is provided and comprises a semiconductor substrate 1 and a dielectric layer 3 overlying substrate 1 and having recesses formed in the exposed, upper surface 4 thereof. Recesses 2 formed in the upper, exposed surface 4 of dielectric layer 3 may be utilized for forming vias, inter-level metallization, and/or interconnection routing of at least one active device region or component formed on or within semiconductor substrate 1.

As shown in FIG. 2B, in some embodiments, a barrier layer 7 may first be deposited on the surfaces of the recesses to protect against diffusion of a subsequently deposited conductive layer into the surrounding dielectric layer 3. As discussed above, in some embodiments a metal alloy film may provide the necessary barrier against diffusion of the subsequently deposited conductive layer into the surrounding dielectric layer. In these embodiments, barrier layer 7 may be unnecessary or may be formed at a reduced thickness. In the illustrated structures, semiconductor substrate 1 typically comprises a material such as monocrystalline Si or GaAs, dielectric layer 3 comprises an insulative material typically utilized as an inter-layer dielectric (ILD), i.e., an inorganic material such as a silicon oxide, nitride, or oxynitride, or an organic-based or derived material, such as parylene, benzocyclobutene (BCB), etc. Suitable materials for barrier layer 7 include, for example, Ti, W, Cr, Ta, and TaN.

As shown in FIG. 2C, a metal alloy film 8 is deposited on the barrier layer 7 within recesses 2 by, for example, conventional physical vapor deposition (PVD) or chemical vapor deposition (CVD) processes. If a PVD process is used, the target used may comprise the alloyed bulk metal. Alternatively, two targets may be used, a first target comprising a bulk metal and a second target comprising an alloying element. In another alternative embodiment, one target may comprise a bulk metal and another target may comprise two or more alloying elements. Furthermore, a bulk metal layer may first be formed by an electroplating or an electroless plating process. The alloying element may then be introduced into the bulk metal layer by an implantation process.

In preferred embodiments of the present invention, the metal alloy film 8 (for example, alloyed Cu) may comprise two or more alloying elements. The two or more alloying elements may include, but are not limited to, Mg, Ca, Sn, B, C, Pd, Co, Ni, Zr, and Cd. The metal alloy film 8 may be employed to improve the electromigration performance of a subsequently electroplated or electroless plated (“plated”) conductive fill (for example, a plated Cu layer) by diffusing the alloying elements into the conductive fill by, for example, an annealing process.

In some preferred embodiments, the metal alloy film 8 may comprise multiple alloying elements having different physical and/or chemical attributes effective at preventing diffusion of the conductive fill into a surrounding dielectric and/or minimizing or substantially preventing electromigration, for example, along grain boundaries. Thus, the present invention advantageously employs some alloying elements to, for example, minimize or substantially prevent electromigration along grain boundaries, and employs other alloying elements to, for example, prevent diffusion of the conductive fill into a surrounding dielectric and/or minimize or substantially prevent electromigration along the interface between the surface of the conductive fill (such as conductive fill 9′ shown in FIG. 2E) and another surface, for example, the surface of a passivation layer (such as encapsulating layer 13 shown in FIG. 21) or barrier layer (such as barrier layer 7 shown in FIG. 2B).

In some preferred embodiments, a stack of multiple metal alloy films, each comprising one or more alloying elements, may be deposited on the barrier layer 7. Thus, multiple alloying elements having different physical and/or chemical attributes effective at, for example, minimizing or substantially preventing electromigration along grain boundaries and/or along the interface between the surfaces of the conductive fill and another surface may be diffused from the multiple metal alloy films into a subsequently deposited conductive fill.

As an example embodiment of the present invention, a first metal alloy film, for example metal alloy film 8, may be deposited over a barrier layer 7 previously deposited on the recess surfaces (as shown in FIG. 2C). This metal alloy film 8 may comprise magnesium and/or calcium. These alloying elements may have attributes that are beneficial in preventing diffusion of the conductive fill into a surrounding dielectric, i.e., they may act as a diffusion barrier. Thus, the first metal alloy film 8 is advantageously situated adjacent to the barrier layer (or surrounding dielectric in embodiments without the barrier layer), where its physical and/or chemical attributes may be employed most effectively to reduce diffusion of the conductive fill into the surrounding dielectric.

Continuing with this example, a second metal alloy film (not shown) comprising one or more alloying elements having physical and/or chemical attributes effective at minimizing or substantially preventing electromigration along grain boundaries may be deposited over the first metal alloy film. Thus, the second metal alloy film is advantageously situated so that it surrounds a subsequently deposited conductive fill where its physical and/or chemical attributes may most effectively reduce or substantially eliminate electromigration by more easily diffusing the alloying elements into (“stuffing”) the grain boundaries within the conductive fill.

In an alternative embodiment of the present invention, a single metal alloy film, for example, metal alloy film 8 in FIG. 2C, comprising one or more alloying elements, may be deposited over barrier layer 7. One or more of the alloying elements may have, for example, physical and/or chemical attributes effective at preventing diffusion of the conductive fill into a surrounding dielectric and/or minimizing or substantially preventing electromigration along grain boundaries. In addition, or in the alternative, one or more alloying elements may have, for example, physical and/or chemical attributes effective at minimizing or substantially preventing electromigration along the interface between the surfaces of the conductive fill and another surface, for example barrier layer 7.

Thus, in the embodiment where only one metal alloy film is deposited, the metal alloy film may be situated adjacent to both a barrier layer, for example, barrier layer 7, and a subsequently deposited conductive fill. This metal alloy film may advantageously comprise two or more alloying elements which may have physical and/or chemical attributes effective at minimizing or substantially preventing diffusion of the conductive fill into a surrounding dielectric and/or preventing electromigration along the grain boundaries of the conductive fill and/or along an interface between the conductive fill and another surface.

Referring now to FIG. 2D, subsequent to the deposition of one or more metal alloy films, a layer of conductive metal 9, for example, Cu or Cu-based alloy, is deposited by conventional plating techniques, for example electroplating or electroless plating techniques, to fill the recesses 2. In order to ensure complete filling of the recesses, the conductive metal 9 is deposited as a blanket (or “overburden”) layer of excess thickness so as to overfill the recesses 2 and cover the upper surface 4 of the dielectric layer 3.

Next, as shown in FIG. 2E, at least a portion of and preferably the entire excess thickness t of the overburden layer of conductive metal 9 over the surface of the dielectric layer 3, as well as the metal alloy film 8 over the upper surface of the dielectric 3 (or barrier layer 7), may be removed by, for example, a CMP process utilizing an alumina (A12O3)-based slurry, leaving conductive fill 9 in the recesses 2 with exposed upper surfaces 10 substantially co-planar with the surface 4 of the dielectric layer 3.

As shown in FIG. 2F, according to a preferred embodiment of the present invention, at least one alloying layer 11 comprising one or more alloying elements is deposited on the upper, exposed surfaces, 10 and 4, respectively, of the conductive fill 9′ and the dielectric layer 3 as by a suitable PVD technique, including, but not limited to, sputtering, ion plating, electroplating, and vacuum evaporation. In one preferred embodiment, the alloying element is zirconium. Zirconium may have attributes that are beneficial in improving the adhesion between the conductive fill and a subsequently formed passivation layer or other layer in contact with the conductive fill. In a preferred embodiment, the zirconium concentration within the bulk material is between 0.05 and 5 percent. The thickness of alloying layer 11 may be within the range of 500 to 3000 Angstroms (A), preferably 1000 A. Suitable thickness(es) for the alloying layer(s) may be chosen for use in a particular application.

Alloying layer 11 may, depending, inter alia, upon the particular conductive metal 9 and choice of alloying element(s), comprise a single layer including one or more alloying elements, for example two alloying elements, or alternatively, can comprise a stack of two or more alloying layers, one deposited over the other, each containing one or more alloying elements. The latter alternative may be preferred when co-deposition of multiple alloying elements in single layer form is impractical or results in poor control of the relative amounts of the alloying elements, and therefore, poor composition control and/or uniformity of the desired alloy.

Referring now to FIG. 2G, according to a preferred embodiment, the at least one alloying layer 11 is subjected to a treatment for effecting diffusion of the one or more alloying elements into and alloying with the underlying conductive metal of the conductive fill 9′, as, for example, by a thermal treatment. More specifically, diffusion/alloying can be effected by annealing at an elevated temperature in an inert atmosphere, for example nitrogen (N₂) or a rare gas such as argon (Ar). The resulting structure contains the heat treated alloying layer portions 11′ and an alloyed portion 12, over the unalloyed conductive fill 9′. In one embodiment, the annealing temperatures for an alloying layer comprising zirconium and a conductive fill comprising Cu may be within the range of 30 to 500 degrees Centigrade, preferably between 200 and 400 degrees Centigrade. Suitable annealing conditions for use with other alloying elements and metal features may be chosen for use in a particular application.

The diffusion/alloying treatment provides a planarized, inlaid metallization pattern having the alloyed portion 12 to a depth d below the upper surface 10 of the alloyed portion 12. In one embodiment employing zirconium as the alloying element and Cu as the conductive fill, the depth of alloyed portion 12 may be within a range of between 500 and 3000 A, preferably 1000 A. A suitable depth for use with other alloying elements and metal features may be chosen for use in a particular application.

As illustrated in FIG. 2G, alloying layer portions 11′ may remain on or over the upper surfaces 10 and 4, respectively, of the alloyed portion 12 and the dielectric layer 3 after completion of the diffusion/alloying treatment. Referring now to FIG. 2H, according to a preferred embodiment, any such remaining alloying layer portions 11′ may be removed, for example, by etching or CMP.

Referring now to FIG. 2I, an encapsulating layer 13 may be deposited over the upper surfaces 10 and 4 after completion of the removal of any remaining alloying layer portions 11′. Encapsulating layer 13 may act as a passivation layer to encapsulate and protect the metallization features or as an etch stop layer for protection during processing of further layers. Encapsulating layer 13 may comprise, for example, silicon nitride.

In further embodiments of the present invention, one or more additional alloying layers, each comprising one or more alloying elements, may be deposited on the planarized upper surfaces 10 and 4 after the planarization step shown in FIG. 2H. Another diffusion/alloying treatment may then be performed for effecting diffusion of the one or more alloying elements into and alloying with the underlying conductive metal of the conductive fill 9′. Subsequent planarization and passivation layer deposition steps may then be performed as described above in relation to FIGS. 2H and 2I, respectively.

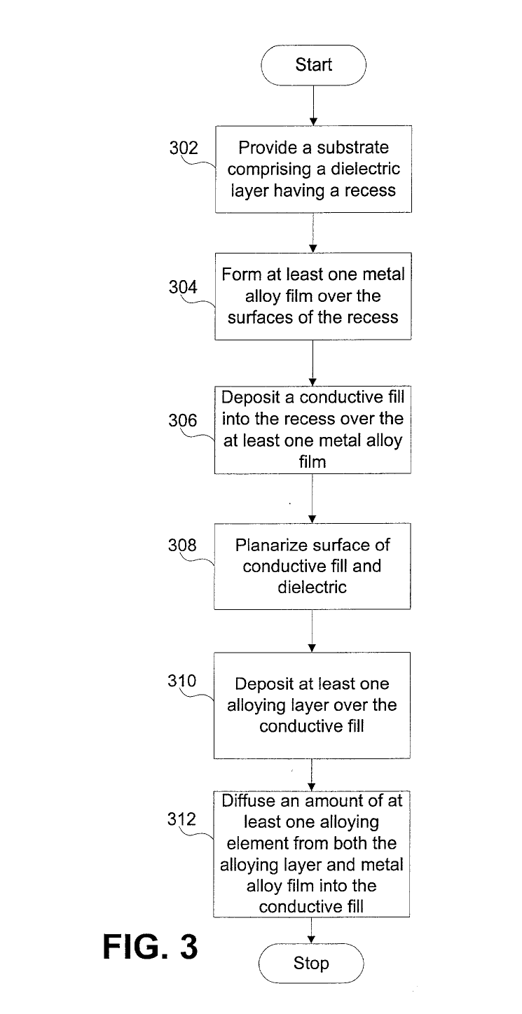

FIG. 3 shows a process flow diagram illustrating an embodiment of the present invention. The process flow diagram encompasses the preferred embodiment of the present invention, as well as other alternative embodiments. Initially, at 302, a substrate is provided comprising a dielectric layer having a recess. Next, at 304, at least one metal alloy film is formed over the surfaces of the recess. Next, at 306, a conductive fill is deposited into the recess over the metal alloy film. Next, at 308, a planarization step is performed such that the surface of the conductive fill is substantially coplanar with the surface of the dielectric layer. Next, at 310, at least one alloying layer is deposited over the conductive fill. Then, at 312, an amount of at least one alloying element is diffused from both the alloying layer and metal alloy film into the conductive fill. The diffusion may be performed simultaneously or separately optimized for each alloying element as by sequentially controlling the temperature and time of an annealing process. In alternative embodiments, a first annealing process may be performed after 306 in order to diffuse alloying elements within the metal alloy film into the conductive fill. A subsequent annealing process may then be performed at 312 in order to diffuse alloying elements within the alloying layer into the conductive fill.

During the conventional process for forming a pattern of damascene-type, inlaid Cu metallization features, as shown in FIGS. 1A through 1C, in some instances, for example as with unalloyed Cu inlaid metal features, the Cu metallization features tend to form a weaker interface with the barrier and passivation materials than comparable aluminum features. As a result, the interface of a copper interconnect line with the surrounding barrier and dielectric materials can act as a fast diffusion path for electromigration. In addition, the Cu metallization features typically have small metal grains compared to etched metal lines and Cu ions and/or atoms may diffuse faster along grain boundaries than through the bulk of the grains.

Embodiments of the present invention may advantageously diffuse multiple alloying elements into metallization features from one or more alloying layers and metal alloy films which are formed at different stages of the device fabrication process. By forming the alloying layers and metal alloy films at different stages of the fabrication process, the multiple alloying elements may be advantageously situated where their particular beneficial attributes may be employed most effectively.

The multiple alloying elements may have different physical and/or chemical attributes which may be more effective at, for example, minimizing or substantially preventing electromigration along grain boundaries and/or along the interface between the surfaces of the metallization features and other surfaces. Additionally, the multiple alloying elements may have different physical and/or chemical attributes which may minimize or substantially prevent diffusion of the conductive fill into a surrounding dielectric and/or improve the adhesion between the conductive fill and a subsequently formed passivation layer or other layer in contact with the conductive fill.

Further embodiments of the present invention may deposit one or more metal alloy films in combination with one or more alloying layers, the metal alloy films and alloying layers each comprising one or more alloying elements which may have different physical and/or chemical attributes which may provide some or all of the above described benefits.

Embodiments of the present invention thus provide a simple, convenient, and reliable method for reducing, or substantially preventing, deleterious electromigration of metal from inlaid metallization features along grain boundaries and/or along the interface between the surfaces of the metallization features and other surfaces, for example, the surface of a barrier layer or a passivation layer. Furthermore, embodiments of the present invention provide a simple, convenient, and reliable method for minimizing or substantially preventing diffusion of the conductive fill into a surrounding dielectric. In addition, embodiments of the present invention provide a simple, convenient, and reliable method for improving the adhesion between the conductive fill and a subsequently formed passivation layer or other layer in contact with the conductive fill.

Embodiments of the present invention enable the formation of extremely reliable interconnect members and patterns, illustratively, but not limited to, Cu, by providing a method for reliably reducing, or substantially preventing, deleterious electromigration. Embodiments of the present invention also provide a substantial increase in the reliability of damascene-type metallization patterns utilized in semiconductor “back-end” processing and is equally applicable to “dual-damascene” type processing.

Embodiments of the present invention enjoy particular utility in the manufacture of semiconductor devices having sub-micron dimensioned metallization features and high aspect ratio openings. Moreover, embodiments of the present invention can be practiced according to requirements for economic competitiveness, and are fully compatible with conventional process flow for automated manufacture of high-density integration semiconductor devices. In addition, the embodiments of the present invention are particularly well suited to the manufacture of circuit boards and other types of electrical and electronic devices and/or components.

In the previous description, numerous specific details are set forth, such as specific materials, structures, reactants, processes, etc., in order to provide a better understanding of the present invention. However, the present invention can be practiced without resorting to the details specifically set forth. In other instances, well known processing materials and techniques have not been described in detail in order not to unnecessarily obscure the present invention.

Only the preferred embodiment of the present invention and but a few examples of its versatility are shown and described in the present disclosure. It is to be understood that the present invention is capable of use in various other combinations and environments and is susceptible of changes or modifications within the scope of the inventive concept as expressed herein.

What is claimed is:

1. A method of manufacturing an electrical device, the method comprising:
providing a substrate comprising a dielectric layer having a recess therein;
forming at least one metal alloy film on surfaces of the recess;
forming a conductive fill over the at least one metal alloy film;
planarizing the conductive fill and the dielectric layer;
forming at least one alloying layer comprising at least one alloying element on the conductive fill; and
diffusing an amount of the at least one alloying element from the at least one alloying layer into the conductive fill.

2. The method recited in claim 1, further comprising removing at least a portion of the at least one alloying layer from the conductive fill.

3. The method recited in claim 1, wherein the at least one metal alloy film comprises two or more alloying elements and wherein the method further comprises diffusing an amount of the two or more alloying elements from the at least one metal alloy film into the conductive fill.

4. The method recited in claim 3, wherein the two or more alloying elements of the at least one metal alloy film comprise at least one alloying element that reduces electromigration of the conductive fill along grain boundaries of the conductive fill.

5. The method recited in claim 3, wherein the two or more alloying elements of the at least one metal alloy film comprise at least one alloying element that reduces electromigration of the conductive fill at an interface of the conductive fill and another surface.

6. The method recited in claim 3, wherein the two or more alloying elements of the at least one metal alloy film comprise at least one alloying element that reduces electromigration of the conductive fill along grain boundaries of the conductive fill and at least one different alloying element that reduces electromigration of the conductive fill at an interface of the conductive fill and another surface.

7. The method recited in claim 3, wherein the two or more alloying elements of the at least one metal alloy film comprise at least one alloying element that reduces diffusion of the conductive fill into a surrounding dielectric.

8. The method recited in claim 1, wherein the at least one alloying layer comprises two or more alloying elements.

9. The method recited in claim 8, wherein the two or more alloying elements of the at least one alloying layer comprise at least one alloying element that reduces electromigration of the conductive fill along grain boundaries of the conductive fill.

10. The method recited in claim 8, wherein the two or more alloying elements of the at least one alloying layer comprise at least one alloying element that reduces electromigration of the conductive fill at an interface of the conductive fill and another surface.

11. The method recited in claim 8, wherein the two or more alloying elements of the at least one alloying layer comprise at least one alloying element that reduces electromigration of the conductive fill along grain boundaries of the conductive fill and at least one different alloying element that reduces electromigration of the conductive fill at an interface of the conductive fill and another surface.

12. The method recited in claim 8, wherein the two or more alloying elements of the at least one alloying layer comprise at least one alloying element that increases adhesion at an interface of the conductive fill and another surface.

13. The method recited in claim 1, wherein the at least one metal alloy film comprises a stack of two or more metal alloy films, each comprising at least one alloying element.

14. The method recited in claim 13, wherein at least one of the two or more metal alloy films comprise at least one alloying element that reduces electromigration of the conductive fill along grain boundaries of the conductive fill.

15. The method recited in claim 13, wherein at least one of the two or more metal alloy films comprise at least one alloying element that reduces electromigration of the conductive fill at an interface of the conductive fill and another surface.

16. The method recited in claim 13, wherein at least one of the two or more metal alloy films comprise at least one alloying element that reduces electromigration of the conductive fill along grain boundaries of the conductive fill and at least one different alloying element that reduces electromigration of the conductive fill at an interface of the conductive fill and another surface.

17. The method recited in claim 13, wherein at least one of the two or more metal alloy films comprise at least one alloying element that reduces diffusion of the conductive fill into a surrounding dielectric.

18. The method recited in claim 1, wherein the at least one metal alloy film comprises a copper alloy film.

19. The method recited in claim 1, wherein the at least one alloying layer comprises a stack of two or more alloying layers, each comprising at least one alloying element.

20. The method recited in claim 1, wherein the conductive fill comprises copper.

21. The method recited in claim 1, wherein the at least one alloying layer is formed by a physical vapor deposition (PVD) process.

22. The method recited in claim 21, wherein the at least one alloying layer is formed by one of sputtering, ion plating, electroplating, and vacuum evaporation.

23. The method recited in claim 1, wherein the conductive fill and the dielectric layer are planarized by a chemical-mechanical polishing (CMP) process.

24. The method recited in claim 1, wherein the amount of the at least one alloying element is diffused from the at least one alloying layer into the conductive fill by an annealing process.

25. The method recited in claim 2, wherein the portion of the at least one alloying layer is removed from the conductive fill by a chemical-mechanical polishing (CMP) process.

26. The method recited in claim 1, wherein the electrical device comprises a semiconductor integrated circuit device; and
wherein the substrate comprises a semiconductor material comprising one of monocrystalline silicon (Si) and gallium arsenide (GaAs).

27. The method recited in claim 1, wherein the at least one alloying element of the at least one alloying layer is selected from the group consisting of zirconium (Zr), tin (Sn), boron (B), magnesium (Mg), carbon (C), palladium (Pd), cobalt (Co), nickel (Ni), and cadmium (Cd).

28. The method recited in claim 3, wherein the two or more alloying elements of the at least one metal alloy film are selected from the group consisting of magnesium (Mg), calcium (Ca), tin (Sn), boron (B), carbon (C), palladium (Pd), cobalt (Co), nickel (Ni), zirconium (Zr), and cadmium (Cd).

29. The method recited in claim 1, further comprising:
forming at least one additional alloying layer comprising at least one alloying element on the conductive fill after removing the at least one alloying layer from the conductive fill;
diffusing an amount of the at least one alloying element from the at least one additional alloying layer into the conductive fill; and
removing the at least one additional alloying layer from the conductive fill.
